(19) United States
(12) Patent Application Publication
(10) Pub. No.: US 2014/0000686 A1
(43) Pub. Date: Jan. 2, 2014

(54) FILM STACK AND PROCESS DESIGN FOR BACK PASSIVATED SOLAR CELLS AND LASER OPENING OF CONTACT

(71) Applicant: Applied Materials, Inc., Santa Clara, CA (US)

(72) Inventors: Hemant P. MUNGEKAR, Campbell, CA (US); Jeffrey L. FRANKLIN, Albuquerque, NM (US); Yi ZHENG, Sunnyvale, CA (US); Lin ZHANG, San Jose, CA (US); Manoj VELLAIKAL, Sunnyvale, CA (US)

(21) Appl. No.: 13/794,238

(22) Filed: Mar. 11, 2013

Related U.S. Application Data
(60) Provisional application No. 61/666,533, filed on Jun. 29, 2012.

(51) Int. Cl. H01L 31/0216; H01L 31/18

(52) U.S. Cl. CPC H01L 31/02167; H01L 31/18
USPC 136/252; 438/98

(57) ABSTRACT

Embodiments of the invention relate to methods for fabricating a passivation layer stack for photovoltaic devices. In one embodiment, the passivation layer stack comprises a first dielectric layer of AlₓO_{y} (or SiOₓ) and a second dielectric layer of SiₓN_{y} having a refractive index less than 2.1. The passivation layer stack has contact openings formed therethrough by a series of pulsed laser beams having a wavelength of about 300-700 nm and a pulse width of about 0.01 nanosecond to about 3 nanoseconds. Lowering the refractive index of SiₓN_{y} capping AlₓO_{y} (or SiOₓ) in the passivation layer stack makes pulsed laser beams less selective since the SiₓN_{y} absorbs less laser energy. Therefore, desired regions of the entire passivation layer stack can be removed smoothly in a single pass of pulsed laser beams at a shorter wavelength without causing damage to the neighborhood of the passivation layer stack.

### CROSS-REFERENCE TO RELATED APPLICATIONS

This application claims benefit of U.S. Provisional Patent Application Ser. No. 61/666,533, filed Jun. 29, 2012, entitled “FILM STACK AND PROCESS DESIGN FOR BACK PASSIVATED SOLAR CELLS AND LASER OPENING OF CONTACT”, which is herein incorporated by reference.

### BACKGROUND

1. Field

Embodiments of the present invention generally relate to the fabrication of solar cells and particularly to the back surface passivation of silicon solar cells.

2. Description of the Related Art

Solar cells are photovoltaic devices that convert sunlight directly into electrical power. The most common solar cell material is silicon, which is in the form of single, polycrystalline, multi-crystalline substrates, or amorphous films. Efforts to reduce the cost of manufacturing solar cells, and thus the cost of the resulting cell, while maintaining or increasing the overall efficiency of the solar cell produced are ongoing.

The efficiency at which a solar cell converts incident light energy into electrical energy is adversely affected by a number of factors, including the fraction of incident light that is reflected off the light receiving surface of a solar cell and/or not reflected off the back surface of a solar cell, and the recombination rate of electrons and holes in a solar cell. When electrons and holes recombine, the incident solar energy is re-emitted as heat or light, thereby lowering the conversion efficiency of the solar cells. Recombination may occur in the bulk silicon of a substrate, which is a function of the number of defects in the bulk silicon, or on the front or back surface of a substrate, which is a function of how many dangling bonds, i.e., unterminated chemical bonds (manifesting as trap sites), are on the substrate surface. Dangling bonds are typically found on the surface of the substrate because the silicon lattice of substrate ends at the front or back surface. These dangling bonds act as defect traps and therefore are sites for recombination of electron-hole pairs.

The efficiency of a solar cell may be enhanced by use of a passivation layer on the back surface of a solar cell. A good passivation layer can provide a desired film property that reduces recombination of the electrons or holes in the solar cells, and redirects electrons and charges back into the solar cells to generate photocurrent. Furthermore, the passivation layer may also serve as a backside reflector to minimize light absorption while assisting reflecting light back to the solar cell devices.

In order to passivate a n-type emitter surface for a p-type base solar cell, for example, a passivation layer, for example an aluminum oxide (such as Al₂O₃) layer or a silicon oxide layer (such as SiO₂), may be formed on the back surface of the silicon substrate. Aluminum oxide or silicon dioxide is not only effective in passivating the dangling bonds, but also has effective fixed charge to improve field effect passivation. A silicon nitride (SiN) layer may be further deposited on the aluminum oxide layer (or silicon dioxide layer if used) to prevent the aluminum oxide or silicon dioxide from reacting with a later-deposited metal back contact material (e.g., Al) during the subsequent high-temperature anneal process, sometimes referred to as a firing process. The passivation film stack (i.e., Al₂O₃/SiN or SiO₂/SiN) is then patterned by a laser ablation process to form contact openings through which a portion of the metal back contact material can be extended to form electrical contact between the metal back contact and the p-type base region for current extraction.

However, laser ablation of multiple layers in a passivation film stack as described above is confronted with a number of challenges. For example, a conventional infrared (IR) laser, which has a wavelength of 1064 nanometers (nm) corresponding to a photon energy of 1.16 electron volts (eV), has been reported to be unable to ablate dielectric materials such as silicon nitride and aluminum oxide (or silicon dioxide if used). This is because the photon energy of IR laser is only higher than the band gap of silicon (1.12 eV), but less than that of silicon nitride (5.1 eV) and aluminum oxide (8.7 eV) or silicon dioxide (8.9 eV). When a laser's photon energy is less than a material's band gap, the material is transparent to the laser. Therefore, conventional IR lasers will penetrate deep into and damage the silicon base region, rather than on the silicon nitride and aluminum oxide (or silicon dioxide) that need to be ablated. Laser beams with shorter wavelengths and higher photon energies, for example, ultraviolet (UV) lasers (157 nm or 7.8 eV photon energy), can be effective in ablating the silicon nitride layer. However, the underlying layer (i.e., aluminum oxide or silicon dioxide) is sill transparent to UV lasers due to different optical absorption coefficient and band gap between the silicon nitride and aluminum oxide or silicon dioxide. As a result, only the silicon nitride layer is removed instead of the entire passivation film stack getting removed. In order to have the entire passivation film stack removed, one would have to perform multiple laser ablation processes or at least two ablation processes with a different laser power suitable for aluminum oxide or silicon dioxide ablation, which renders production throughput to decrease. Even if the UV laser power is set with the highest ablation threshold to ablate the underlying aluminum oxide (or silicon dioxide) layer, the intense UV laser power would be too strong for the silicon nitride ablation, causing thermal-induced damage to the neighborhood of the passivation layer stack.

Therefore, there exists a need for an improved passivation film stack with film properties so that desired regions of the passivation film stack can be removed effectively by a laser without causing damages to the neighborhood of the passivation layer stack.

### SUMMARY OF THE INVENTION

Embodiments of the invention generally relate to methods for fabricating photovoltaic devices, and more particularly relate to methods of forming a passivation layer stack on a surface (e.g., a p-type emitter surface) of a silicon-based substrate. In one embodiment, a method of manufacturing a solar cell device is provided. The method generally includes providing a substrate into a processing chamber, wherein the substrate has a light receiving surface and a back surface that is generally parallel and opposite to the light receiving surface, forming a passivation layer stack on the substrate. The process of forming the passivation layer stack includes forming a first dielectric layer on the back surface of the substrate, and forming a second dielectric layer over the first dielectric layer, wherein the second dielectric layer has a refractive index less than 2.1 (e.g., 1.9), subjecting the passivation layer to a series of pulsed laser beams having a wavelength of about 200 nm to about 700 nm and a pulse width of between about 0.01 nanosecond to about 10 nanoseconds to remove the second and first dielectric layers at once at desired regions in the passivation layer stack, forming a plurality of contact openings in the passivation layer stack that each extends through the second and first dielectric layers to the back surface of the substrate. In an alternative embodiment, a third dielectric layer is formed between the first and second dielectric layers, and the third dielectric layer has a refractive index between 1.7 and 1.9. The intensity distribution of the laser beam output may have a top-hat or predominantly substantially uniform irradiance profile. In one example, the first dielectric layer is aluminum oxides or silicon oxides such as silicon dioxide. The second dielectric layer is silicon nitrides (Si₃H₄). The third dielectric layer is silicon oxynitride (SiON).

In another embodiment, a solar cell device is provided. The solar cell generally includes a substrate having a first surface and a second surface that is generally parallel and opposite to the first surface, an emitter region formed on the first surface of the substrate, the emitter region having a conductivity type opposite to a conductivity type of the substrate, and a passivation layer stack. The passivation layer stack has a first dielectric layer formed on the second surface of the substrate, and a second dielectric layer formed over the first dielectric layer, wherein the second dielectric layer has a refractive index less than 2.1 (e.g., 1.9), a mass density of about 2.7 g/cm³, and a hydrogen content (H) less than about 15 atomic %. The passivation layer stack has a plurality of contact openings extending through the second dielectric layer and the first dielectric layer to the second surface of the substrate. In an alternative embodiment, a third dielectric layer is formed between the first and second dielectric layers, and the third dielectric layer has a refractive index between 1.7 and 1.9. In one example, the first dielectric layer is aluminum oxides or silicon oxides such as silicon dioxide. The second dielectric layer is silicon nitrides (Si₃H₄). The third dielectric layer is silicon oxynitride (SiON), and the first dielectric layer has a thickness of about 200 Å, the second dielectric layer has a thickness of about 800 Å, and the third dielectric layer has a thickness of about 100 Å. The passivation layer may have a total thickness of about 1000 Å to about 1600 Å.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1D illustrate schematic cross-sectional views of a solar cell device during different stages in a processing sequence of FIG. 2 according to various embodiments of the invention.

FIG. 2 depicts a flow diagram illustrating a processing sequence of forming a solar cell device according to the embodiment shown in FIGS. 1A-1D.

FIGS. 3A and 3B are illustrations describing laser beam intensity distribution according to one embodiment of the invention.

### DETAILED DESCRIPTION

Embodiments of the invention generally relate to methods for fabricating photovoltaic devices, and more particularly relate to methods of forming a passivation layer stack on a surface (e.g., a p-type emitter surface) of a silicon-based substrate. The passivation layer stack is formed between the silicon-based substrate and a back metal contact layer. In one embodiment, the passivation layer stack includes an aluminum oxide (or silicon dioxide) layer and a silicon nitride layer. The aluminum oxide layer (or silicon dioxide) is about 200 Å thick and silicon nitride layer is deposited in a manner such that the silicon nitride is formed with a thickness of about 800 Å and a refractive index (n) of 1.7 to 1.9 at a wavelength of 633 nm, giving a total passivation layer stack thickness of about 1000 Å. The proposed passivation layer stack advantageously makes the laser ablation process less selective by lowering the refractive index of the layer (i.e., silicon nitride) capping the aluminum oxide layer (or silicon dioxide if used) in the passivation layer stack to less than 2.1 such that the silicon nitride layer absorbs less laser energy. Therefore, while the silicon nitride layer is being ablated, a great deal of laser energy that would have been absorbed by the silicon nitride is instead absorbed by the underlying aluminum oxide layer (or silicon dioxide layer). As the silicon nitride absorbs less energy, a desired region of the entire passivation layer stack can be removed smoothly in a single pass of pulsed laser beams without causing damages to the neighborhood of the passivation layer stack, even if an intense UV or green laser (required for ablation of aluminum oxide or silicon dioxide to occur) is used.

In another embodiment, the passivation layer stack may include an aluminum oxide layer, a silicon nitride layer, and a silicon oxynitride layer sandwiched between the aluminum oxide layer and the silicon nitride layer. The silicon oxynitride layer is deposited in a manner such that the silicon oxynitride is formed with a thickness of about 100 Å and a refractive index (n) of 1.7 to 1.9 at a wavelength of 633 nm. The aluminum oxide layer and the silicon nitride layer may have a thickness of about 200 Å and about 800 Å, respectively. The use of the intermediate silicon oxynitride layer reduces the thickness of the underlying aluminum oxide layer required for the passivation layer stack since silicon oxynitride layer provides optical properties similar to the aluminum oxide layer (n≈1.7). Therefore, the amount of expensive aluminum oxides to be, used is reduced. In addition, due to similarities between silicon oxynitride and aluminum oxide in terms of the optical properties, a desired region of the entire passivation layer stack can still be removed in a single pass of pulsed laser energy without causing damages to the neighborhood of the passivation layer stack, even if an intense UV or green laser is used.

### Exemplary Passivation Layer Stack and Forming Process Thereof

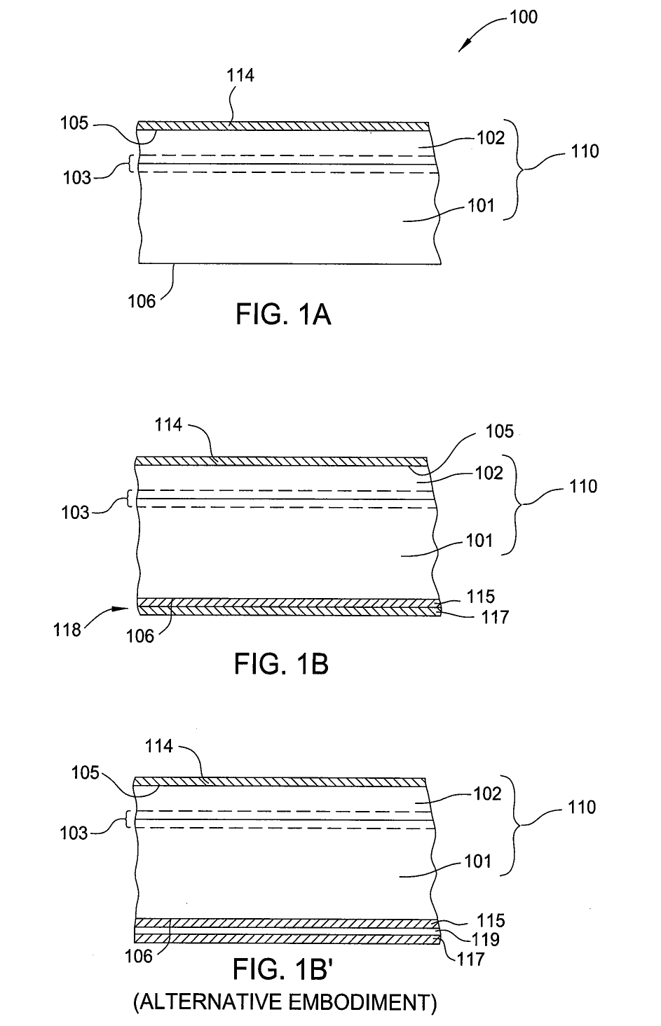

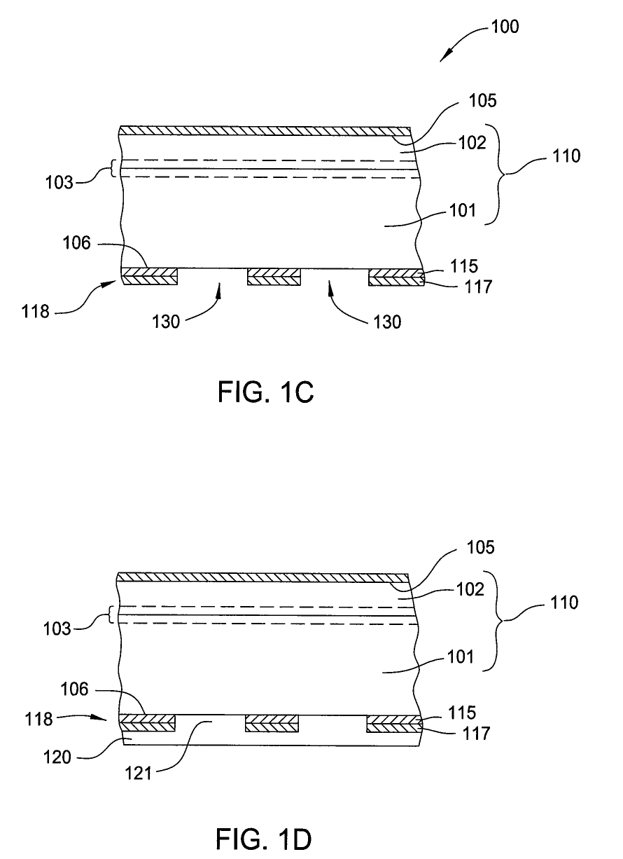

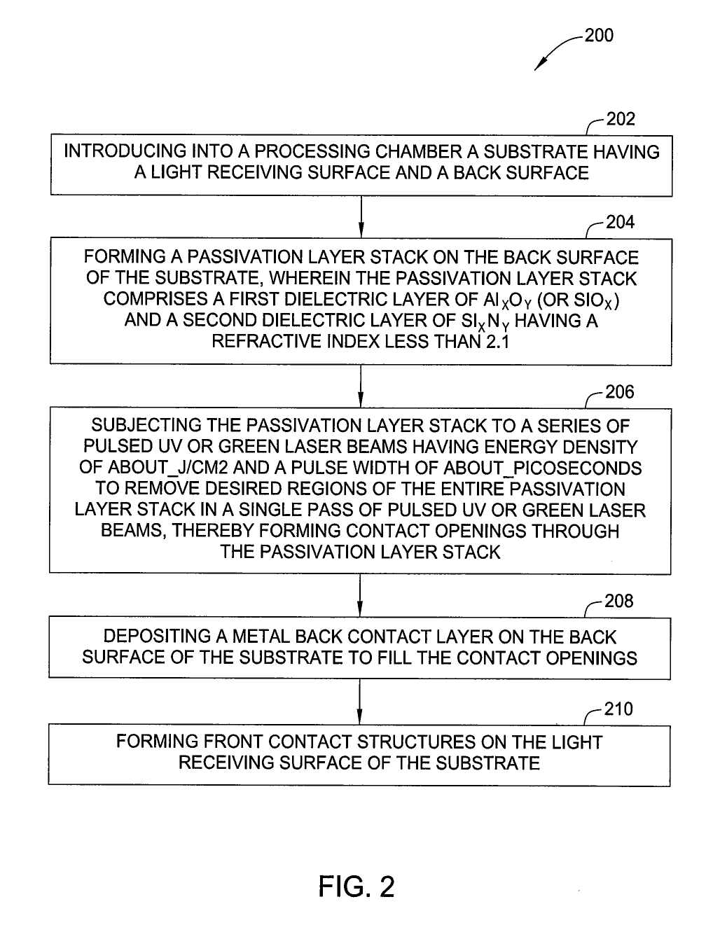

FIGS. 1A-1D illustrate schematic cross-sectional views of a solar cell device 100 during different stages in a processing sequence of FIG. 2 according to one embodiment of the invention. FIG. 2 is a flow diagram 200 illustrating a processing sequence of forming a solar cell device 100 according to the embodiment shown in FIGS. 1A-1D. It is noted that the processing sequences depicted in FIG. 2 are only used as an example of a process flow that can be used to manufacture a solar cell device. Some steps may be added or eliminated as needed to form a desirable solar cell device. The processes sequence of FIG. 2 may be performed in a single substrate processing chamber, or in multiple substrate processing chambers provided in a cluster tool. One will note that, in some cases, each of the processes may be performed in an oxygen-free inert and/or vacuum environment, such as in the vacuum processing regions of a cluster tool, so that the substrate is not exposed to oxygen between the processes.

The flow diagram 200 begins at box 202 by introducing a substrate 110 into a processing chamber, such as a plasma enhanced chemical vapor deposition (PECVD) chamber. An example of the PECVD chamber is a PRODUCER® Chamber, which is commercially available from Applied Materials, Inc. of Santa Clara, Calif. The substrate 110 generally has a base region 101, an emitter region 102, and a p-n junction region 103 disposed between the base region 101 and the emitter region 102, as shown in FIG. 1A. The substrate 110 may be a single crystal or multicrystalline silicon substrate, silicon containing substrate, doped (with p-type or n-type dopants) silicon containing substrate, or other suitable substrates. In one configuration, the substrate 110 is a p-type crystalline silicon (c-Si) substrate. P-type dopants used in silicon solar cell manufacturing are chemical elements, such as, boron (B), aluminum (Al) or gallium (Ga). In another configuration, the substrate 110 may be an electronic grade silicon substrate or a low lifetime, defect-rich silicon substrate, for example, an upgraded metallurgical grade (UMG) crystalline silicon substrate. The upgraded metallurgical grade (UMG) silicon is a relatively clean polysilicon raw material having a low concentration of heavy metals and other harmful impurities, for example in the parts per million range, but which may contain a high concentration of boron or phosphorus, depending on the source. In certain applications, the substrate can be a back-contact silicon substrate prepared by emitter wrap through (EWT), metallization wrap around (MWA), or metallization wrap through (MWT) approaches. Although the embodiment depicted herein and relevant discussion thereof primarily discuss the use of a p-type c-Si substrate, this configuration is not intended to be limiting as to the scope of the invention, since an n-type c-Si substrate may also be used without deviating from the basic scope of the embodiments of the invention described herein. The doping layers or emitters formed over the substrate will vary based on the type of substrate that is used, as will be discussed below.

The substrate 110 has a light receiving surface (i.e., front surface 105) and a bottom or back surface 106 opposing the light receiving surface. The emitter region 102 may be an n-type emitter region formed by doping a deposited semiconductor layer with certain types of elements (e.g., phosphorus (P), arsenic (As), or antimony (Sb)) using any suitable techniques, such as an implant process (followed by an anneal process) or a thermal diffusion process using a phosphosilicate glass (PSG), in order to increase the number of negative charge carriers, i.e., electrons. The p-n junction region 103 is the region in which electron-hole pairs are generated when solar cell device 100 is illuminated by incident photons of light. An anti-reflective coating, such as passivation ARC layer 114, may be deposited on the light receiving surface 105 of the solar cell device 100. The passivation ARC layer 114 may include silicon oxide, silicon nitride, or a combination thereof.

At box 204, a passivation layer 118 is formed on the back surface 106 of the base region 101 formed in the substrate 110. The passivation layer 118 may include a first dielectric layer 115 and a second dielectric layer 117 formed on the first dielectric layer 115 of the substrate 110. The passivation layer 118 provides good interface properties that reduce the recombination of the electrons and holes, drives and/or diffuses electrons and charge carriers. The first and second dielectric layers 115, 117 may be fabricated from a dielectric material selected from the group consisting of silicon oxide (SiₓO_{y}), silicon nitride (SiₓN_{y}), silicon nitride hydride (SiₓN_{y}:H), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), Hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide, aluminum oxide (AlₓO_{y}), aluminum nitrite, or aluminum oxynitride.

In one embodiment, the first dielectric layer 115 is silicon oxides, such as silicon dioxide (SiO₂) and the second dielectric layer 117 is silicon nitrides, such as silicon nitride (Si₃N₄). In another embodiment, the first dielectric layer 115 is aluminum oxides (Al₂O₃) and the second dielectric layer 117 is silicon nitrides, such as silicon nitride (Si₃N₄). In either case, the first dielectric layer 115 may have a thickness of about 200 Å to about 600 Å and the second dielectric layer 117 may have a thickness of about 800 Å to about 1000 Å, giving a total passivation layer stack thickness of about 1000 Å to about 1600 Å. The second dielectric layer 117 may be deposited to provide a refractive index (n) less than 2.1, such as 1.9 at a wavelength of 622 nm.

The inventors have determined that lowering the refractive index of the layer (i.e., silicon nitride) capping the aluminum oxide layer (or silicon dioxide if used) in the passivation layer stack to less than 2.1 may lead to ease and uniform ablation of the silicon nitride layer without causing damages to the neighborhood of the passivation layer stack. This is because refractive index of a material is proportional to absorption coefficient of the material according to Kramers-Kronig equation. Since silicon nitrides with lower refractive index tend to absorb less laser energy, the silicon nitride layer in the passivation layer stack can be ablated smoothly even if an intense UV or green laser (required for ablation of aluminum oxide or silicon dioxide to occur, will be discussed below) is used. In addition, as the silicon nitride layer absorbs less laser energy, the laser ablation process is less selective since a great deal of laser energy that would have been absorbed by the silicon nitride is instead absorbed by the underlying aluminum oxide or silicon dioxide layer. As a result, a desired region of the entire passivation layer stack can be removed in a single pass of pulsed laser energy, as opposed to multiple passes of pulsed laser energy that would otherwise required by the conventional laser ablation process. Therefore, the production throughput is increased.

In yet another embodiment as shown in FIG. 1B′ (Alternative Embodiment), a third dielectric layer 119 may be formed between the first dielectric layer 115 and the second dielectric layer 117. The first and second dielectric layers 115, 117 may be any of those materials mentioned above. The third dielectric layer 119 may be any dielectric material that has optical properties close to the first dielectric layer 115. In one example where the first dielectric layer 115 is aluminum oxide, the third dielectric layer 115 is silicon oxynitride (SiON). In such a case, the silicon oxynitride is deposited to provide a refractive index (n) ranging between 1.7 and 1.9 at a wavelength of 622 nm. In various examples of this embodiment, the first dielectric layer 115 may have a thickness of about 100 Å to about 300 Å, the second dielectric layer 117 may have a thickness of about 800 Å to about 1000 Å, and the third dielectric layer 119 may have a thickness of about 100 Å to about 300 Å, giving a total passivation layer stack thickness of about 1000 Å to about 1600 Å.

The use of the third dielectric layer 119 reduces the thickness of the underlying first dielectric layer 115 required for the passivation layer stack since the third dielectric layer 119 provides optical properties similar to the first dielectric layer 115. This is beneficial when expensive material such as aluminum oxides is used for the first dielectric layer 115. Silicon oxynitrides, which may be used as the third dielectric layer 119, is relatively cheaper to manufacture as compared to the aluminum oxides. Also, the optical propertie of the silicon oxynitride, such as refractive index, is close to that of the aluminum oxide (n≈1.7). Therefore, while providing optical properties similar to the underlying aluminum oxide layer, the amount of expensive aluminum oxides to be used can be reduced. Most importantly, a desired region of the first and third dielectric layers 115, 119 (including the second dielectric layer 117 capping the first and third dielectric layer 115, 119) can still be removed in a single pass of pulsed laser energy without causing damages or cracking to the neighborhood of the passivation layer stack.

Deposition processes that may be used to form the dielectric layers with the desired optical properties in the passivation layer stack 118 are now discussed. The first dielectric layer 115 may be formed by introducing a first process gas mixture into a process volume of a PECVD processing chamber and generating a plasma in the process volume. In cases where the first dielectric layer 115 is silicon dioxide (SiO₂), the first process gas mixture may comprise a silicon-containing gas, an oxidizing gas and/or a carrier gas (e.g., helium). The silicon-containing gas may be selected from a group consisting of silane, disilane, chlorosilane, dichlorosilane, trichlorosilane, dibromosilane, trimethylsilane, tetramethylsilane, tridimethylaminosilane (TriDMAS), tetraethoxysilane (TEOS), triethoxyfluorosilane (TEFS), silicon tetrachloride, silicon tetrabromide, 1,3,5,7-tetramethylcyclotetrasiloxane (TMCTS), dimethyldiethoxy silane (DMDE), octomethylcyclotetrasiloxane (OMCTS), methyldiethoxysilane (MDEOS), bis(tertiary-butylamino)silane (BTBAS), or combinations thereof. The oxidizing gas may be selected from the group consisting of consisting of oxygen (O₂), nitrous oxide (N₂O), ozone (O₃), and combinations thereof.

During deposition of the silicon dioxide, the silicon-containing gas may be flowed into the PECVD processing chamber at a flow rate of about 20 standard cubic centimeter per minute (sccm) to about 20000 sccm, and the oxidizing gas may be flowed into the processing chamber at a flow rate of about 20 sccm to about 20000 sccm. The silicon-containing gas may be TEOS and the oxidizing gas may be ozone. The ratio of the silicon-containing gas to the oxidizing gas may be from about 0.005:1 to about 100:1, such as about 0.05:1 to about 50:1, for example 3:1. The chamber pressure may be between about 1 Torr and about 60 Torr, such as between about 2 Torr and about 10 Torr. The electrode spacing (i.e., a distance between a showerhead and a substrate support) may be maintained between about 50 mils and about 2000 mils. For processing a 300 mm substrate, the plasma may be provided by RF power from about 50 W to about 12000 W, such as about 4500 W, at a frequency of 13.56 MHz. The RF power for the first dielectric layer deposition may generate a plasma for a period of time of about 10 seconds to about 360 seconds. The first dielectric layer 115 may be deposited at 80 angstroms (Å) per minute to about 800 Å per minute, such as about 500 Å/min, and at a substrate support temperature of between about 250° C. and about 650° C. The formed first dielectric layer 115 may have a thickness between about 25 Å and 1,000 Å, such as between about 100 Å and about 450 Å.

In cases where the first dielectric layer 115 is aluminum oxide (Al₂O₃), an aluminum-containing gas, such as trimethylaluminum (TMA), may be flowed into the PECVD processing chamber at a flow rate of about 5 sccm to about 85 sccm, and an oxygen-containing gas, such as oxygen (O₂) or nitrous oxide (N₂O), may be flowed into the PECVD processing chamber at a flow rate of about 25 sccm to about 350 sccm. The aluminum-containing gas and the oxygen-containing gas may be introduced into the chamber at a ratio of between about 1:1 and about 1:5. The chamber pressure may be maintained between about 2 Torr and about 8 Torr, with an RF power of about 50 W to about 6000 W, at a frequency of 13.56 MHz, an electrode spacing of about 50 mils to about 2000 mils, and a substrate support temperature of between about 250° C. and about 400° C. The RF power for the first dielectric layer deposition may generate a plasma for a period of time of about 10 seconds to about 45 seconds. The first dielectric layer 115 may be deposited at 250 Å or more per minute, such as about 500 Å/min. The formed first dielectric layer 115 may have a thickness between about 50 Å and 1,000 Å, such as between about 100 Å and about 450 Å. It is contemplated that the first dielectric layer 115 may be deposited using any suitable deposition techniques, for example, a chemical vapor deposition (CVD), an atomic layer deposition (ALD) process, or a physical vapor deposition (PVD) process.

Once the first dielectric layer 117 has been formed on the back surface 106 of the substrate 110, the second dielectric layer 117 is deposited on the first dielectric layer 117. The second dielectric layer 117 may be formed in-situ within the same PECVD chamber used to deposit the first dielectric layer 115 to avoid vacuum break between the depositions. The second dielectric layer 117 may be formed by introducing a second process gas mixture into the process volume of the PECVD processing chamber and generating a plasma in the process volume. In cases where the second dielectric layer 117 is silicon nitrides, such as silicon nitride (Si₃N₄), the second process gas mixture may comprise a silicon-containing gas, a nitrogen-containing gas and/or a carrier gas. For example, the second process gas mixture may be a combination of silane (SiH₄) and nitrogen (N₂), silane and ammonia (NH₃), or silane, ammonia, and nitrogen. The silicon-containing gas may be those mentioned above with respect to the first dielectric layer 115. If desired, a hydrogen gas may be flowed along with the second process gas mixture.

During deposition of the silicon nitride, the silicon-containing gas may be flowed into the PECVD processing chamber at a flow rate of about 20 sccm to about 10000 sccm, and the nitrogen-containing gas may be flowed into the PECVD processing chamber at a flow rate of about 800 sccm to about 50000 sccm. Alternatively, it is contemplated that the silicon-containing gas may be continuously flowed into the PECVD processing chamber during deposition of the first dielectric layer 115 (e.g., silicon dioxide) and the second dielectric layer 117 (e.g., silicon nitride), while adjusting the flow rate of the nitrogen-containing gas to obtain silicon nitride with desired refractive index. In either case, the ratio of the silicon-containing gas to the nitrogen-containing gas may be from about 5:1 to about 15:1, such as about 10:1. The chamber pressure may be between about 2 Torr and about 10 Torr. The electrode spacing may be maintained between about 50 mils and about 2000 mils. For processing a 300mm substrate, the plasma may be provided by an RF power of about 50 W to about 6000 W, at a frequency of 13.56 MHz. The RF power for the first dielectric layer deposition may generate a plasma for a period of time of about 20 seconds to about 600 seconds. To further densify the second dielectric layer 117, a substrate bias power may be applied to effectuate ion bombardment on the surface of the second dielectric layer 117. In such a case, the substrate bias power may be between about 0.002 W/cm² and about 0.5 W/cm². The second dielectric layer 117 may be deposited at about 250 Å or more per minute, such as about 500 Å/min, and at a substrate support temperature of between about 350° C. and about 650° C. The formed second dielectric layer 117 may have a thickness between about 350 Å and 900 Å, such as between about 600 Å and about 800 Å. In various embodiments, the passivation layer 118 may have a total thickness between about 800 Å and 1000 Å.

### EXAMPLES

### Example 1

A passivation layer stack using a silicon dioxide or aluminum oxide (i.e., the first dielectric layer 115) and a silicon nitride (i.e., the second dielectric layer 117) is formed on a back surface of a p-type doped region of a substrate for a solar cell device. The silicon dioxide, aluminum oxide, and silicon nitride layers are formed according to the following process conditions shown in Tables 1 and 2. The deposition is performed on a substrate area of 1,200×1,300 mm, which may be used to carry up to 56 wafers in a 7×8 arrangement.

TABLE 1

| | Silicon Dioxide | Aluminum Oxide |
|---|---|---|
| Deposition Time (Sec.) | 24 | 24 |
| Dep. Rate (Å/min.) | 500 | 500 |
| RF Power (W) | 4500 | 4500 |
| Pressure (mTorr) | 6 | 6 |
| Substrate Temperature (° C.) | 350 | 350 |
| Electrode Spacing (mils) | 800 | 800 |
| Gas chemistry: TEOS/O₃ (sccm) | 120/450 | n/a |
| Gas chemistry: TMA/N₂O (sccm) | n/a | 56/200 |
| Refractive Index | 1.7 | 1.65 |
| Mass density (g/cm³) | 2.30 | 2.76 |
| Thickness (Å) | 200 | 200 |

TABLE 2

| | Silicon Nitride |
|---|---|
| Deposition Time (Sec.) | 110 |
| Dep. Rate (Å/min.) | 500 |
| RF Power (W) | 4500 |
| Pressure (Torr) | 6 |
| Substrate Temperature (° C.) | 350 |
| Electrode Spacing (mils) | 800 |
| Gas chemistry: SiH₄/N₂O (sccm) | 65/200 |
| Refractive Index | 1.9 |
| Mass density (g/cm³) | 2.50 |
| Thickness (Å) | 800 |

In one embodiment where the passivation layer stack has a third dielectric layer 119 formed between the first dielectric layer 115 and the second dielectric layer 117 (FIG. 1B′), a third process gas mixture may be introduced into the PECVD processing chamber prior to deposition of the second dielectric layer 117. In cases where the third dielectric layer 119 is silicon oxynitride, the third process gas mixture may comprise a silicon-containing gas, a nitrogen-containing gas and/or an oxygen-containing gas. The silicon-containing gas, the nitrogen-containing gas, and the oxygen-containing gas may be those mentioned above with respect to the first and second dielectric layers 115, 117. For example, the silicon-containing gas may be SiH₄, the nitrogen-containing gas may be N₂ or NH₃, and the oxygen-containing gas may be N₂O. Similarly, the third dielectric layer 119 may be formed in-situ within the same PECVD chamber used to deposit the first and second dielectric layer 115, 117, thereby avoiding vacuum break between the depositions.

During deposition of the third dielectric layer 119, the silicon-containing gas may be flowed into the PECVD processing chamber at a flow rate of about 20 sccm to about 10000 sccm, the nitrogen-containing gas may be flowed into the PECVD processing chamber at a flow rate of about 50 sccm to about 20000 sccm, and the oxygen-containing gas may be flowed into the PECVD processing chamber at a flow rate of about 20 sccm to about 10000 sccm. In one example, the silicon-containing gas is SiH₄, the nitrogen-containing gas is N₂, and the oxygen-containing gas is N₂O. The ratio of the silicon-containing gas to the nitrogen-containing gas and the oxygen-containing gas may be from about 1:10:0.01 to about 1:100:0.5, such as about 1:50:0.3. The chamber pressure may be between about 1 Torr and about 10 Torr, such as between about 2 Torr and about 6 Torr. The electrode spacing may be maintained between about 200 mils and about 2000 mils. The plasma may be provided by RF power of about 50 W to about 6000 W, at a frequency of 13.56 MHz. The RF power density for the first dielectric layer deposition may generate a plasma for a period of time of about 20 seconds to about 90 seconds. The third dielectric layer 119 may be deposited at 250 Å or more per minute, such as about 500 Å/min, and at a substrate support temperature of between about 200° C. and about 650° C. The formed third dielectric layer 119 may have a thickness between about 100 Å and 300 Å, such as between about 200 Å. In this embodiment, the passivation layer 118 may have a total thickness between about 1000 Å and 1600 Å.

### Example 2

A passivation layer stack using a silicon dioxide or aluminum oxide (i.e., the first dielectric layer 115), an intermediate silicon oxynitride (i.e., the third dielectric layer 119), and a silicon nitride (i.e., the second dielectric layer 117) is formed on a back surface of a p-type doped region of a substrate for a solar cell device. The silicon dioxide, aluminum oxide, and silicon nitride layers are formed according to the conditions shown in Tables 1 and 2, and the silicon oxynitride layer is formed according to the following conditions shown in Table 3. The deposition is performed on a substrate area of 1,200×1,300 mm.

TABLE 3

| | Silicon Oxynitride |
|---|---|
| Deposition Time (Sec.) | 45 |
| Dep. Rate (Å/min.) | 500 |
| RF Power (W) | 4500 |
| Pressure (Torr) | 6 |
| Substrate Temperature (° C.) | 350 |
| Electrode Spacing (mils) | 800 |
| Gas chemistry: SiH₄/N₂/N₂O (sccm) | 85/4.5 slm/30 |
| Refractive Index | 1.75 |
| Mass density (g/cm³) | 2.81 |
| Thickness (Å) | 100 |

At box 206, after the passivation layer 118 has been formed on the back surface 106 of the substrate 110, a laser patterning process may be performed in a laser processing chamber to form a plurality of contact openings 130 in the passivation layer 118. The contact openings 130 expose a portion of the back surface 106 of the substrate 110, as shown in FIG. 1C. The plurality of contact openings 130 are formed through the passivation layer 118 to enable an electrical connection between the base region 101 and a subsequently deposited metal back contact 121 (FIG. 1D) utilized for current extraction. Each contact opening 130 within the passivation layer 118 may be spaced at an equal distance to each other. Alternatively, each contact opening may be configured to have different distances to one another.

The laser patterning process may be performed in an inert (such as N₂) environment to prevent oxidation of the exposed surface of the substrate 110 or to encourage removal of debris or unablated films. The laser patterning process may be performed by delivering one or more pulsed laser beams to portions of the passivation layer 108 to form a desired pattern of contact openings 130 extending through the second dielectric layer 117 and the first dielectric layer 115, or extending through the second dielectric layer 117, the third dielectric layer 119, and the first dielectric layer 115 in certain embodiments. The pulsed laser beam output may be between about 1 W and about 20 W, for example between about 5 W and about 10 W. The pulsed laser beam may have a shorter wavelength between about 200 nm and about 700 nm, for example 532 nm, or any wavelength with a corresponding pulse energy suitable for removing the first, second and third dielectric layers 115, 117, 119. In cases where the desired region of the passivation layer is not completely ablated, a subsequent wet cleaning process may be performed to make sure a good metal contact is obtained between the subsequently deposited metal back contact and the silicon base region.

The pulsed laser beam may be in the wavelength range of 300 nm to 700 nm. In one embodiment, the pulsed laser beam is an UV laser (wavelength: 355 nm) having energy density (e.g., fluence) of about 0.1 Joule per square centimeter (J/cm²) and about 10 J/cm², for example about 1 J/cm². In another embodiment, the pulsed laser beam is a green laser (wavelength: 532 nm or 523.5 nm) having energy density of about 0.1 J/cm² and about 1.0 J/cm². In either case, the pulse frequency of the laser beam may be between about 30 kHz and about 70 kHz, such as 50 kHz. The pulsed laser beam may have a pulse width between about 80 picoseconds and about 50 nanoseconds, for example about 1 nanosecond to about 10 nanoseconds, such as about 0.01 nanosecond to about 3 nanoseconds. The spot size of the pulsed laser beam may be controlled at between about 80 μm and about 100 μm in diameter. The laser energy of the pulsed laser beam is believed to produce laser energy of between about 1 eV per photon and about 50 eV, which is sufficient to ablate the first dielectric layer 115, second dielectric layer 117, and third dielectric layer 119 (if used) in the passivation layer stack 118. The laser patterning process with the proposed laser energy forms a contact opening 130 with a diameter ranging between about 20 μm to about 200 μm, and a pitch (e.g., contact spacing between centers of contact openings) of about 100 μm to about 1000 μm. Some exemplary process parameters that may be used to ablate dielectric layers in the passivation layer 118 are shown in Table 4.

TABLE 4

| | 355 nm | 532 nm (Ultra) | 532 nm (Bryce) |
|---|---|---|---|
| Pulse width 0 | <15 ps | <10 ps | <10 ps |
| Power (W) | 1.07 | 1.93 | 15.9 |
| Pulse Energy (μJ) | 21.4 | 38.6 | 63.6 |
| Pulse Frequency (kHz) | 50 | 50 | 50-600 |
| Beam Diameter (μm) | 120 | 140 | 90 |
| Flounce (J/cm²) | 0.092 | 0.159 | 1.06 |

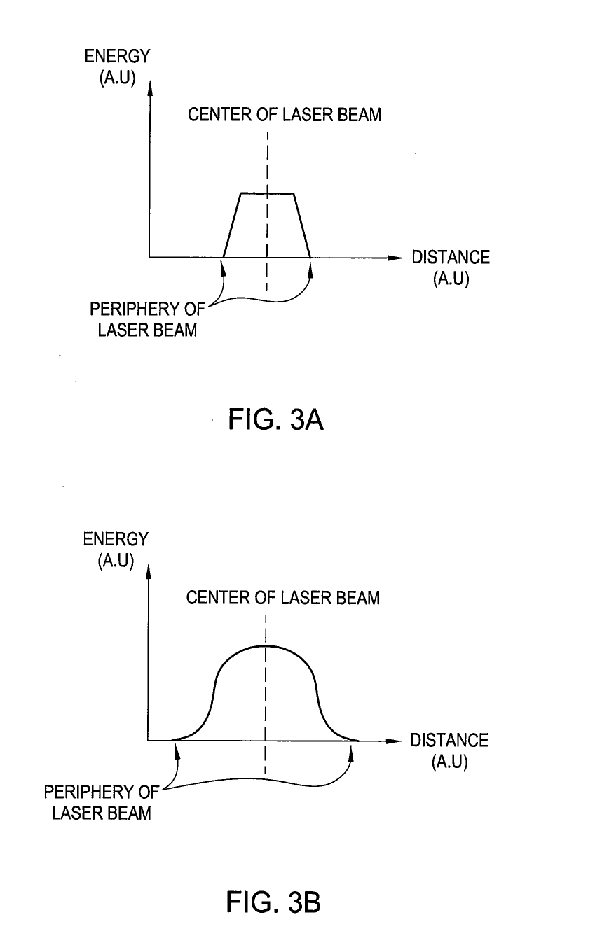

In certain embodiments, the shape of the intensity distribution of the laser beam output does not have to be circular but instead may be modified to a “top-hat” profile (FIG. 3A), as opposed to a commonly used Gaussian shape (FIG. 3B) laser beam intensity distribution, to ablate the spotted region uniformly. Typically, a laser beam intensity distribution has a Gaussian irradiance profile (bell-shaped) in the plane perpendicular to the propagation of the laser beam, as shown in FIG. 3B. If the raw laser Gaussian irradiance profile is shaped into a “top-hat” or predominantly substantially uniform irradiance profile, as shown in FIG. 3A, the imaged shaped output beam will have a substantially uniform intensity laser spot from its center to its periphery so that high quality contact openings can be ablated rapidly, without risk of bottom damage or having un-ablated film on the periphery of the laser beam spot. It is contemplated that the laser beam could also be aligned, for example, by repeating laser irradiation about 10 times or hundreds of times to align the silicon surface orientation to (111) plane, to take advantage of preferred Al alloying with Si on the (111) planes during the subsequent firing process.

At box 208, a metal back contact layer 120 is deposited on the back surface of the substrate 110, i.e., the surface of the second dielectric layer 117. The metal back contact layer 120 fills the contact openings 130 in the passivation layer 118 to form backside contacts 121, as shown in FIG. 1D. The metal back contact layer 120 is a conductive material such as aluminum, silver, nickel, alloys thereof, combinations thereof, and any other conductive material compatible with solar cell technology. The metal back contact layer 120 may be deposited using a PVD process, an electroless deposition process, or any other conductive material deposition process.

At box 210, after the backside contacts 121 are formed, the substrate 110 is removed from the laser processing chamber and a front metallization process may be performed to form front contact structures and/or conductive bus-lines on the passivation ARC layer 114 of the substrate 110. Further deposition steps or processing steps (such as a firing process) that may be required to manufacture the solar cell device 100 can be conducted depending upon the application and are not discussed herein.

Embodiments of the invention generally provide improved passivation layer stack for a solar cell device and laser ablation processes for forming contact openings in the passivation layer stack. The methods advantageously making the laser ablation process less selective by lowering the refractive index of the layer (i.e., silicon nitride) capping the aluminum oxide layer (or silicon dioxide if used) in the passivation layer stack to less than 2.1 such that the silicon nitride layer in the passivation layer stack absorbs less laser energy. Therefore, while the silicon nitride layer is being ablated, a great deal of laser energy that would have been absorbed by the silicon nitride is instead absorbed by the underlying aluminum oxide or silicon dioxide layer. As a result, a desired region of the entire passivation layer stack can be removed in a single pass of pulsed laser energy, as opposed to multiple passes of pulsed laser energy that would otherwise required by the conventional laser ablation process. Therefore, the production throughput is increased. In addition, the desired region of the entire passivation layer stack can be removed without causing damage or cracking to the neighborhood of the passivation layer stack, even if an intense UV or green laser (required for ablation of aluminum oxide or silicon dioxide to occur) is used. Therefore, the electrical performance of the solar cell devices is improved.

While the foregoing is directed to embodiments of the present invention, other and further embodiments of the invention may be devised without departing from the basic scope thereof, and the scope thereof is determined by the claims that follow.

What is claimed is:

1. A method of manufacturing a solar cell device, comprising:
providing a substrate into a processing chamber, the substrate has a light receiving surface and a back surface that is generally parallel and opposite the light receiving surface;
forming a passivation layer stack on the substrate;
subjecting the passivation layer stack to a series of pulsed laser beams having a wavelength of about 300 nm to about 700 nm, and a pulse width of between about 80 picoseconds and about 50 nanoseconds to remove entire materials of the passivation layer stack at desired regions; and
forming a plurality of contact openings in the passivation layer stack so that each contact opening extends through the passivation layer stack to the back surface of the substrate.

2. The method of claim 1, wherein forming the passivation layer stack further comprises:
forming a first dielectric layer on the back surface of the substrate; and
forming a second dielectric layer over the first dielectric layer, wherein the second dielectric layer has a refractive index less than 2.1.

3. The method of claim 2, wherein the first dielectric layer has a thickness of about 100 Å to about 300 Å and the second dielectric layer has a thickness of about 800 Å to about 1000 Å.

4. The method of claim 1, wherein the pulsed laser beams have a wavelength of 355 nm or 532 nm.

5. The method of claim 2, wherein the second dielectric layer has a refractive index of about 1.9.

6. The method of claim 2, further comprising:
forming a third dielectric layer between the first and second dielectric layers, wherein the third dielectric layer has a refractive index between 1.7 and 1.9.

7. The method of claim 6, wherein the first dielectric layer, the second dielectric layer and the third dielectric layer are fabricated from a material selected from the group consisting of silicon oxide (SiₓO_{y}), silicon nitride (SiₓN_{y}), silicon nitride hydride (SiₓN_{y}:H), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), Hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide, aluminum oxide (AlₓO_{y}), aluminum nitrite, or aluminum oxynitride.

8. The method of claim 7, wherein the first dielectric layer is silicon dioxide or aluminum oxide, the second dielectric layer is silicon nitride (Si₃H₄), and the third dielectric layer is silicon oxynitride.

9. The method of claim 1, wherein the series of pulsed laser beams have a pulse width of between about 0.1 nanosecond and about 10 nanoseconds.

10. The method of claim 6, wherein the third dielectric layer has a thickness of about 100 Å to about 300 Å.

11. The method of claim 1, wherein the intensity distribution of the laser beam output has a top-hat profile.

12. A solar cell device, comprising:
a substrate having a first surface and a second surface, the second surface being generally parallel and opposite the first surface;
an emitter region formed on the first surface of the substrate, the emitter region having a conductivity type opposite to a conductivity type of the substrate; and
a passivation layer stack, comprising:
a first dielectric layer formed on the second surface of the substrate; and
a second dielectric layer formed over the first dielectric layer, wherein the second dielectric layer has a refractive index less than 2.1, a mass density of about 2.7 g/cm³, and a hydrogen content (H) less than about 15 atomic %.

13. The device of claim 12, wherein the passivation layer stack has a plurality of contact openings extending through the second dielectric layer and the first dielectric layer to the second surface of the substrate.

14. The device of claim 12, wherein the second dielectric layer has a refractive index of about 1.9.

15. The device of claim 12, further comprising:
a third dielectric layer sandwiched between the first and second dielectric layers, wherein the third dielectric layer has a refractive index between 1.7 and 1.9.

16. The device of claim 15, wherein the first dielectric layer, the second dielectric layer and the third dielectric layer are fabricated from a material selected from the group consisting of silicon oxide (SiₓO_{y}), silicon nitride (SiₓN_{y}), silicon nitride hydride (SiₓN_{y}:H), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), Hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide, aluminum oxide (AlₓO_{y}), aluminum nitrite, or aluminum oxynitride.

17. The device of claim 12, wherein the passivation layer has a total thickness of about 800 Å to about 1000 Å.

18. The device of claim 12, wherein the second dielectric layer has a mass density of about 2.7 g/cm³ and a hydrogen content (H) less than about 15 atomic %.

19. A method of manufacturing a solar cell device, comprising:
providing a substrate having a passivation layer stack on the substrate, wherein the passivation layer stack has a first dielectric layer and a second dielectric layer formed over the first dielectric layer, wherein the second dielectric layer has a refractive index less than 2.1; and
subjecting the passivation layer stack to a series of pulsed laser beams having a wavelength of about 300 nm to about 700 nm, and a pulse width of between about 0.01 nanosecond to about 3 nanoseconds to remove the first dielectric layer and the second dielectric layer at once at desired regions in the passivation layer stack.

20. The method of claim 19, wherein the first dielectric layer and the second dielectric layer are fabricated from a material selected from the group consisting of silicon oxide (SiₓO_{y}), silicon nitride (SiₓN_{y}), silicon nitride hydride (SiₓN_{y}:H), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), Hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide, aluminum oxide (AlₓO_{y}), aluminum nitrite, or aluminum oxynitride.
